(19) United States
(12) Patent Application Publication
(10) Pub. No.: US 2008/0124827 A1
(43) Pub. Date: May 29, 2008

(54) Method and structure for manffacturing long-wavelength visible light-emitting diode using prestrained growth effect

(76) Inventors: Chi-Feng Huang, Taoyuan City (TW); Tsung-Yi Tang, Taipei (TW); Jeng-Jie Huang, Yi Chu Shiang (TW); Wen-Yu Shiao, Wurih Township (TW); Horng-Shyang Chen, Fongshan City (TW); Chih-Feng Lu, Wang-an Township (TW); Jian-Jang Huang, Taipei City (TW); Chih-Chung Yang, Taipei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/819,520

(22) Filed: Jun. 28, 2007

(30) Foreign Application Priority Data
Nov. 29, 2006 (TW) 095144211

(51) Int. Cl. H01L 33/00

(52) U.S. Cl. 438/47; 257/E33.008

(57) ABSTRACT

A method and structure for manufacturing long-wavelength visible light-emitting diode (LED) using the prestrained growth effect comprises the following steps: Growing a strained low-indium-content InGaN layer on the N-type GaN layer, and then growing a high-indium-content InGaN/GaN single- or multiple-quantum-well light-emitting structure on the low-indium-content InGaN layer to enhance the indium content of the high-indium quantum wells and hence to elongate the emission wavelength of the LED. The method of the invention can elongate emission wavelength of the LED by more than 50 nm (nanometer) such that an originally designated green LED can emit red light or orange light without influencing other electrical properties.

### FIELD OF THE INVENTION

The present invention relates to a light-emitting diode (LED), and more particularly to a method and a structure for manufacturing a long-wavelength visible LED using the pre-strained growth effect.

### BACKGROUND OF THE INVENTION

In the efforts of manufacturing efficient nitride-based white-light devices, phosphor-free light emitting diodes (LEDs) with stacked quantum wells of different parameters for emitting the three primary colors or two complementary colors have attracted much attention. Currently, the techniques for manufacturing blue- and green-emitting InGaN (indium gallium nitride)/GaN (gallium nitride) quantum-well LEDs are quite mature. However, the technique of manufacturing yellow-red LEDs is still challenging. Although red-emitting InGaN/GaN quantum-well structures have been reported, for practical applications, their inefficient emission or the required complicated process hinders the development of such a device.

Manufacturing longer-wavelength emission (yellow-red) of high efficiency based on InGaN/GaN quantum wells is a crucial issue for the development of solid-state lighting. To elongate the emission wavelength to the yellow-red range, the indium incorporation in the quantum well must be increased. However, the indium incorporation is controlled by the strain condition in the quantum well. The higher indium content in the quantum well will lead to a higher compressive strain in the well layer, resulting in the difficulty of effective indium incorporation. Therefore, stain control becomes a key issue in elongating the emission wavelength. Therefore, the development of a long-wavelength LED based on the InGaN/GaN quantum wells is extremely important.

To overcome the foregoing shortcomings, the inventor(s) of the present invention based on years of experience in the related field to conduct extensive researches and experiments, and finally invented a method and a structure for manufacturing a long-wavelength LED using the prestrained growth effect, as a method or a basis for resolving the foregoing drawbacks.

### SUMMARY OF THE INVENTION

The primary objective of the present invention is to provide a method for manufacturing long-wavelength visible LEDs using the prestrained growth effect. This method can improve the strain resulting from the high indium content in an InGaN/GaN quantum well to effectively incorporate indium. The present invention can efficiently enhance indium content without a complex process. Another objective of the invention is to provide a structure for manufacturing long-wavelength visible LED using the prestrain effect, and the emission wavelength of the LED can be elongated more than 50 nm (nanometer) such that an originally designed green LED can emit red or orange light without significantly influencing other electrical properties.

To achieve the foregoing objectives, the method for manufacturing a long-wavelength LED using the prestrained growth effect comprises the following steps: while manufacturing the LED having the quantum-well layer, growing a low-indium-content quantum-well layer to produce the prestrain effect on the above GaN barrier layer, then growing high-indium-content single or multi-quantum-well layers of enhanced indium contents on the low-indium-content quantum-well layer, thereby elongating the emission wavelength of the LED.

The structure for manufacturing long-wavelength LEDs using the prestrained growth effect includes a low-indium-content quantum well between one or more than one high-indium-content quantum wells and an N-type GaN layer within the LED structure.

In accordance with the method for manufacturing a long-wavelength LED using the prestrain effect, a low-indium-content InGaN layer is grown first to produce tensile strain in the GaN layer above it such that InGaN atoms of bigger sizes can be easily adhered to the layer. Therefore, the indium content in growing the high-indium InGaN/GaN quantum wells will be enhanced.

Accordingly, the subsequently formed quantum-well layers can emit longer-wavelength photons.

To make it easier for our examiner to understand the objective of the invention, its structure, innovative features, and performance, we use preferred embodiments together with the attached drawings for the detailed description of the invention.

### DETAILED DESCRIPTION OF THE PREFERRED EMBODIMENTS

The method for manufacturing a long-wavelength LED using the prestrain effect comprises the following steps: while growing the LED having a single or multi-quantum-well structure, growing a low-indium-content quantum-well layer for the prestrain effect on the GaN barrier layer above it; and growing a high-indium-content single or multi-quantum-well structure above the low-indium-content quantum-well layer for emitting elongated-wavelength photons.

The structure for manufacturing a long-wavelength LED using the prestrain effect comprises a low-indium-content InGaN layer between a high-indium-content quantum well or multi-quantum-well structure and an N-type GaN layer within the LED structure.

The indium concentration of the low-indium-content quantum well is about 7%, and the low-indium-content quantum well can emit violet or ultraviolet light, and the indium concentration of the high-indium-content quantum wells is about 15%.

The foregoing quantum-well layer can be the InGaN/GaN quantum well layer.

The foregoing emission wavelength of the LEDs can be elongated more than 50 nm, such that an originally designated green LED can emit red light or orange light without influencing other electrical properties.

To simplify the illustration, the invention uses metalorganic chemical vapor deposition (MOCVD) to grow the InGaN/GaN quantum-well structures. First, in the InGaN/GaN quantum-well structures, after an N-type GaN layer of 2 μm in thickness is grown at 1070° C. (centigrade), five periods of InGaN/GaN quantum-wells, with 3 nm in the well layer thickness (grown at 680° C.) and 16 nm thickness in the barrier layers then are deposited. The average indium content in the five quantum wells is estimated to be 16%. After the growth of the five-period quantum wells, a P-type Al_{0.2}Ga_{0.8}N layer of 20 nm in thickness, flowed by a P—GaN layer of 120 nm in thickness (both grown at 930° C.), is grown. The described above is used to grow a green LED.

To elongate the emission wavelength, a low-indium-content quantum well is added to produce the prestrain effect. The extra low-indium-content InGaN/GaN quantum well (grown at 745° C.) is inserted between the N-type GaN layer and the five periods of high-indium-content quantum wells. The two barrier layers right below and above the extra quantum well (as the low-indium-content quantum well) are grown at the same temperature as that for the extra quantum well. After the addition of the extra quantum well, the indium contents of the high-indium-content quantum wells are increased to 16-25% from 15-16% as examined with X-ray diffraction (XRD). The indium contents of the high-indium-content quantum wells near the low-indium-content quantum well are higher. The emission wavelengths of the five periods of high-indium-content quantum wells are clearly elongated based on the measurements of the photoluminescence (PL) and cathodoluminescence (CL). The foregoing two epitaxial samples are used to fabricate LEDs. The LED with the prestrained growth emits orange (at around 600 nm) or orange-red light (at around 615 nm) while the LED with the conventional growth emits green light (at around 515 nm).

The low-indium-content quantum well applies the prestrain effect on the barrier layer right above it to increase the indium contents of the high-indium-content quantum wells grown subsequently. Namely, the low-indium-content quantum well (about 7%) induces strained heterojunction to enable the barrier layer to be influenced by tensile strain, thus resulting in better lattice match while growing the quantum wells so as to have higher indium content. Accordingly, the indium content of the quantum wells can be increased by adding the low-indium-content quantum well to elongate the emission wavelength. If the indium content of the low-indium-content quantum well is increased unduly, the prestrain will not occur because this quantum well at the bottom will induce spinodal decomposition to relax strained heterojunction.

In the method for manufacturing a long-wavelength LED using the prestrain effect, a low-indium-content InGaN layer is grown in advance to produce tensile strain on the above GaN layer such that InGaN atoms of bigger sizes can be easily adhered to the GaN layer. Therefore, the indium content in subsequently growing the InGaN quantum wells will be enhanced to elongate the emission wavelength of the fabricated LEDs.

The structure for manufacturing a long-wavelength visible LED using the prestrain effect is that a low-indium-content InGaN layer is inserted between the emitting InGaN/GaN quantum wells and the N-type GaN layer such that better lattice match is provided between the quantum wells and the GaN barrier layers to have higher indium content. Accordingly, the subsequently formed quantum-well layers can have high indium contents to allow the LED to emit longer-wavelength photons such that an originally designed green LED can emit red or orange light without influencing other electrical properties.

The LED structure with the prestrained growth effect can also be an inverted LED. The manufacture process of an inverted LED includes the following steps: growing a P-type GaN layer in advance; then growing light emitting quantum-well layers; and growing an N-type GaN layer. The inverted LED structure includes a low-indium-content InGaN layer between the high-indium-content quantum-well layers and the P-type GaN layer within the LED structure having a single or multi-quantum-well layer.

While the invention has been described by way of example and in terms of a preferred embodiment, it is to be understood that the invention is not limited thereto. To the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method for manufacturing an LED using a prestrained growth effect, said method comprising:
while manufacturing said LED having a quantum-well layer, growing a low-indium-content InGaN layer with said prestrain effect on a GaN barrier layer above, growing a light-emitting quantum-well layer on said low-indium-content InGaN layer to elongate emission wavelength of said LED.

2. The method of claim 1, wherein an indium concentration range of said low-indium-content InGaN layer is about 3-10%.

3. The method of claim 1, wherein said low-indium-content InGaN layer comprises InGaN/GaN quantum wells that include non-luminescent, emitting violet light or ultraviolet light.

4. The method of claim 1, wherein an indium concentration range of said light-emitting quantum-well layer is about 10˜40%.

5. The method of claim 1, wherein said light-emitting quantum-well layer includes InGaN/GaN layers that have a single or multi-quantum-well layer.

6. The method of claim 1, wherein said method further comprises a step of elongating 10 nm or more in the emission wavelength of said LED.

7. The method of claim 1, wherein when said LED emits a green light, the emission wavelength of said LED is elongated to emit yellow, orange or red light.

8. A structure for manufacturing an LED using a prestrained growth effect, said structure comprising:
a low-indium-content quantum-well layer between a high-indium-content quantum-well layer and an N-type GaN layer within the LED structure having a single or multi-quantum-well layer.

9. The structure of claim 8, wherein an indium concentration range of the low-indium-content quantum-well layer is about 3-10%.

10. The structures of claim 8, wherein said low-indium-content quantum-well layer comprises quantum wells that are non-luminescent, emitting violet light or UV light.

11. The structure of claim 8, wherein an indium concentration range of said high-indium-content single or multi-quantum-well layer is about 10-40%.

12. The structure of claim 8, wherein said quantum-well layer comprises InGaN/GaN quantum-well layers.

13. The structure of claim 8, wherein said low-indium content quantum-well layer is also an InGaN thin film.

14. The structure of claim 8, wherein said LED structure further grows a P-type InGaN layer, and then grows a light emitting quantum-well layer, and finally grows an N-type GaN layer, thereby forming an inverted LED structure, and said inverted LED structure includes a low-indium-content InGaN layer between a high-indium-content quantum-well layer and a P-type GaN layer within a LED structure having a single or multi-quantum-well layer.
